(19) United States
(12) Patent Application Publication
(10) Pub. No.: US 2010/0055311 A1
(43) Pub. Date: Mar. 4, 2010

(54) Film Conveyor Apparatus and Roll-to-Roll Vacuum Deposition Method

(75) Inventors: Takayoshi Hirono, Kanagawa (JP); Isao Tada, Kanagawa (JP); Atsushi Nakatsuka, Kanagawa (JP)

Correspondence Address: HARNESS, DICKEY & PIERCE, P.L.C., P.O. BOX 828, BLOOMFIELD HILLS, MI, 48303, US

(73) Assignee: ULVAC, INC, Kanagawa (JP)

(21) Appl. No.: 12/597,916

(22) PCT Filed: Apr. 18, 2008
(86) PCT No.: PCT/JP2008/057600

§ 371 Date: Oct. 28, 2009

(30) Foreign Application Priority Data
May 14, 2007 (JP) 2007127877

(51) Int. Cl. C23C 16/44; C23C 16/00; B65G 13/00

(52) U.S. Cl. 427/255.5; 118/723 R; 193/35 R

(57) ABSTRACT

[Object] To enable a deposition area of a base film to be protected and realize stable film traveling performance.

[Solving Means] A roll-to-roll vacuum deposition apparatus according to the present invention includes a guide unit including a guide roller and an auxiliary roller, the guide roller including a pair of annular guide portions that support side edge portions of a base film, the auxiliary roller being opposed to the guide roller and pressing the side edge portions of the base film against the pair of guide portions. As a result, a deposition area of the base film and roll surfaces of the guide roller and auxiliary roller of the guide unit can be prevented from being brought into contact with each other, and the deposition area) can thus be protected.

### FIELD

The present invention relates to a film conveyor apparatus and a roll-to-roll vacuum deposition method for successively paying out a base film in a reduced-pressure atmosphere and successively taking up the base film while carrying out deposition processing, heating processing, plasma processing, and the like on the traveling base film.

### BACKGROUND

Conventionally, there is known a roll-to-roll vacuum vapor deposition method for depositing, while winding a long base film successively paid out from a payout roller around a cooling roller, an evaporation material from an evaporation source disposed opposite to the cooling roller onto the base film and taking up the base film that has been subjected to the vapor deposition by a take-up roller (see, for example, Patent Document 1 below).

FIG. 5 is a schematic structural diagram of a conventional roll-to-roll vacuum vapor deposition apparatus of this type. In the figure, reference numeral 1 denotes a vacuum chamber, 2 denotes a payout roller, 3 denotes a cooling (or heating) roller (main roller), 4 denotes a take-up roller, and 5 denotes an evaporation source. Guide rollers 6A and 6B are provided between the payout roller 2 and the main roller 3, and guide rollers 7A and 7B are provided between the main roller 3 and the take-up roller 4.

A base film F is a plastic film, a metal foil, or the like and is successively paid out from the payout roller 2 to be supplied to the main roller 3 via the guide rollers 6A and 6B. Then, the base film F is cooled (or heated) by being wound around the main roller 3, and one surface of the base film F is subjected to deposition processing at a position opposed to the evaporation source 5 in this state. The base film F on which a layer is deposited is successively taken up by the take-up roller 4 via the guide rollers 7A and 7B.

Patent Document 1: Japanese Patent No. 3,795,518

Patent Document 2: Japanese Patent Application Laid-open No. 2004-87792

### Problems to be Solved by the Invention

Incidentally, a guide roller constituting the roll-to-roll vacuum vapor deposition apparatus of this type generally has a structure as shown in FIG. 6. A guide roller 8 shown in FIG. 6 includes a cylindrical roll surface 8a that comes into contact with one of the surfaces of the base film F and guides conveyance of the base film F. A surface of the base film F that is brought into contact with and supported by the roll surface 8a changes depending on a position at which the guide roller is disposed in the apparatus. A deposition surface of the base film F is brought into contact with roll surfaces of the guide rollers 6B and 7A shown in FIG. 5, whereas a non-deposition surface of the base film F is brought into contact with roll surfaces of the guide rollers 6A and 7B.

However, there are cases where a deposition area of the base film F cannot be brought into contact with the roll surfaces of the guide rollers depending on a type of the base film F or evaporation material, a deposition form, use conditions of an apparatus, and the like. This is because, if the roll surfaces of the guide rollers are brought into contact with the deposition area of the base film F, a problem that minute scratches are caused in a deposition portion is induced. The deposition area used herein mainly refers to a portion from which side edge portions of the base film are removed.

In this case, a method of structuring a vacuum vapor deposition apparatus so as to support only the non-deposition surface of the base film F as shown in FIG. 7 without using the guide rollers 6B and 7A shown in FIG. 5, for example, so that the deposition surface of the base film F is prevented from being brought into contact with the guide rollers is conceivable. In this method, however, installation positions of the rollers are limited and restrictions in terms of the structure of the apparatus increases.

On the other hand, there is also a method of structuring a guide roller that comes into contact with the deposition surface of the base film F as shown in FIG. 8A (see, for example, Patent Document 2 above). A guide roller 9 shown in FIG. 8A is provided with, on a cylindrical roll surface 9a, a pair of annular guide portions 9b that are formed protrusively while keeping a distance from each other so as to support side edge portions of the base film F. The guide portions 9b support the side edge portions of the base film F as a non-deposition area or unused area so that a deposition area Fc of the base film F is prevented from being brought into contact with the roll surface 9a.

However, since the traveling base film F is long and conveyed while being applied with a tension, a center portion of the traveling base film F may be bent, and the deposition area Fc of the base film F may come into contact with the roll surface 9a of the guide roller 9 as shown in FIG. 8B. In addition, there is a problem that a function of stably guiding the base film F cannot be obtained and a traveling path of the base film F is unsettled, thus interfering take up of the base film F.

The present invention has been made in view of the problems described above, and it is therefore an object of the invention to provide a film conveyor apparatus and a roll-to-roll vacuum deposition method that are capable of protecting a deposition area of a base film and realizing stable traveling performance.

### SUMMARY

### Means for Solving the Problems

According to an embodiment of the present invention, there is provided a film conveyor apparatus conveying a base film in a vacuum chamber, including a payout roller, a take-up roller, and a traveling mechanism. The traveling mechanism is provided between the payout roller and the take-up roller. The traveling mechanism includes a guide unit. The guide unit includes a guide roller and an auxiliary roller. The guide roller has a pair of annular guide portions that support side edge portions of the base film. The auxiliary roller is opposed to the guide roller and presses the side edge portions of the base film against the pair of guide portions.

According to an embodiment of the present invention, there is provided a roll-to-roll vacuum deposition method including successively paying out a base film in a reduced-pressure atmosphere. A layer is deposited on at least one surface of the base film. The base film is nipped at side edge portions thereof and conveyed to a take-up portion.

### BEST MODES FOR CARRYING OUT THE INVENTION

According to an embodiment of the present invention, there is provided a film conveyor apparatus conveying a base film in a vacuum chamber, including a payout roller, a take-up roller, and a traveling mechanism. The traveling mechanism is provided between the payout roller and the take-up roller. The traveling mechanism includes a guide unit. The guide unit includes a guide roller and an auxiliary roller. The guide roller has a pair of annular guide portions that support side edge portions of the base film. The auxiliary roller is opposed to the guide roller and presses the side edge portions of the base film against the pair of guide portions.

In the film conveyor apparatus, the traveling base film is nipped on side edge portions thereof by the guide unit and conveyed to the take-up roller. As a result, a deposition area of the base film and roll surfaces of the guide roller and the auxiliary roller of the guide unit can be prevented from being brought into contact with each other, and the deposition area can thus be protected. Moreover, with such a structure, it becomes possible to realize stable traveling performance of the base film and secure favorable take-up performance of the base film.

Here, the deposition area of the base film refers to a center portion of a deposition surface of the base film that does not come into contact with the guide unit. Such a base film includes a base film in which side edge portions thereof are assumed as unused areas even when deposition is performed on the entire surface of the deposition surface and a base film including a mask for preventing a deposition material from adhering onto side edge portions of the base film.

The film conveyor apparatus may further include any one of a deposition mechanism to deposit a layer on the base film, a heating mechanism to heat the base film, and a plasma processing mechanism to subject the base film to plasma processing, between the payout roller and the take-up roller.

With this structure, it becomes possible to carry out deposition processing, heating processing, or plasma processing on the base film while the base film is traveling.

The auxiliary roller may include a pair of annular press portions that press the side edge portions of the base film against the pair of guide portions at the same time.

With this structure, the deposition area of the base film can be protected.

The auxiliary roller may be provided in a pair so that the side edge portions of the base film can be pressed independently against the pair of guide portions. With this structure, traveling performance of the base film can be controlled as well as optimally adjust a pressing force with respect to each of the edge portions of the base film.

The traveling mechanism may include a main roller that cools or heats the base film by being brought into close contact with a non-deposition surface of the base film. In this case, the guide roller can be provided between the main roller and the take-up roller.

With this structure, the base film can be cooled or heated while the base film is traveling, and favorable take-up performance of the cooled or heated base film can be secured.

Further, according to an embodiment of the present invention, there is provided a roll-to-roll vacuum deposition method including successively paying out a base film in a reduced-pressure atmosphere. A layer is deposited on at least one surface of the base film. The base film is nipped at side edge portions thereof and conveyed to a take-up portion.

In the roll-to-roll vacuum deposition method, the base film on which a layer is deposited is nipped at side edge portions thereof and conveyed to the take-up portion. Accordingly, it is possible to realize stable traveling performance of the base film while protecting a deposition area of the base film and secure favorable take-up performance of the base film.

Hereinafter, embodiments of the present invention will be described with reference to the drawings. It should be noted that in this embodiment, an example in which the present invention is applied to a roll-to-roll vacuum vapor deposition apparatus and a roll-to-roll vacuum vapor deposition method as a film conveyor apparatus and a roll-to-roll vacuum deposition method will be described.

### BRIEF DESCRIPTION OF DRAWINGS

FIG. 1 is a schematic structural diagram of a roll-to-roll vacuum vapor deposition apparatus as a roll-to-roll vacuum deposition apparatus according to an embodiment of the present invention;

FIG. 2 is a side view showing a structural example of a main portion of the roll-to-roll vacuum vapor deposition apparatus shown in FIG. 1;

FIG. 3 is a front view showing a structural example of a guide unit according to the present invention;

FIG. 4 is a front view showing another structural example of the guide unit according to the present invention;

FIG. 5 is a schematic structural diagram of a conventional roll-to-roll vacuum vapor deposition apparatus;

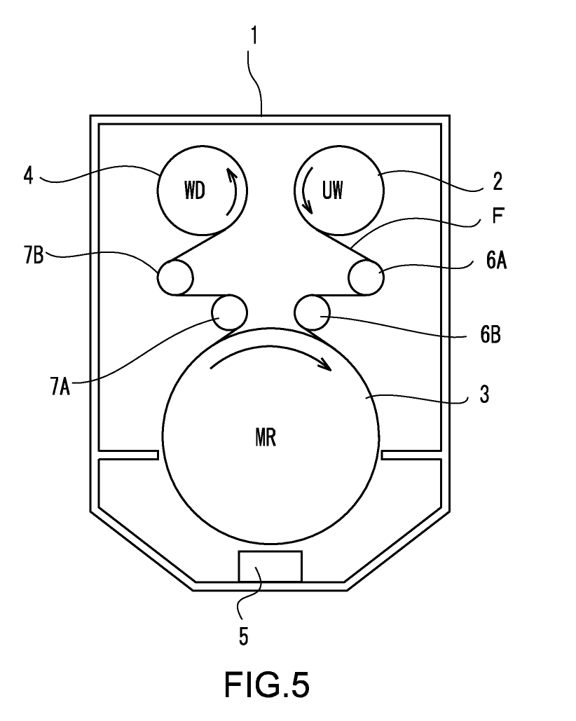

FIG. 6 is a front view showing a structural example of a conventional guide roller;

FIG. 7 is a schematic structural diagram of another conventional roll-to-roll vacuum vapor deposition apparatus; and

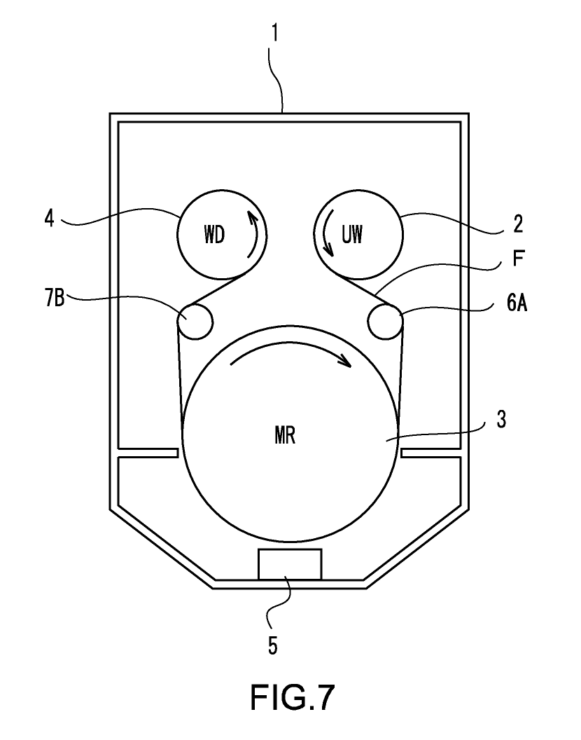

FIG. 8 are front views showing another structural example of the conventional guide roller.

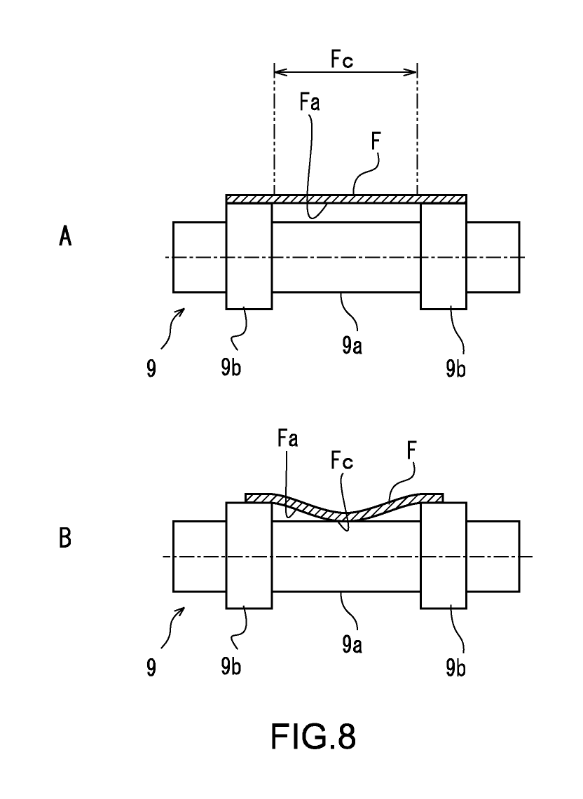

### DETAILED DESCRIPTION

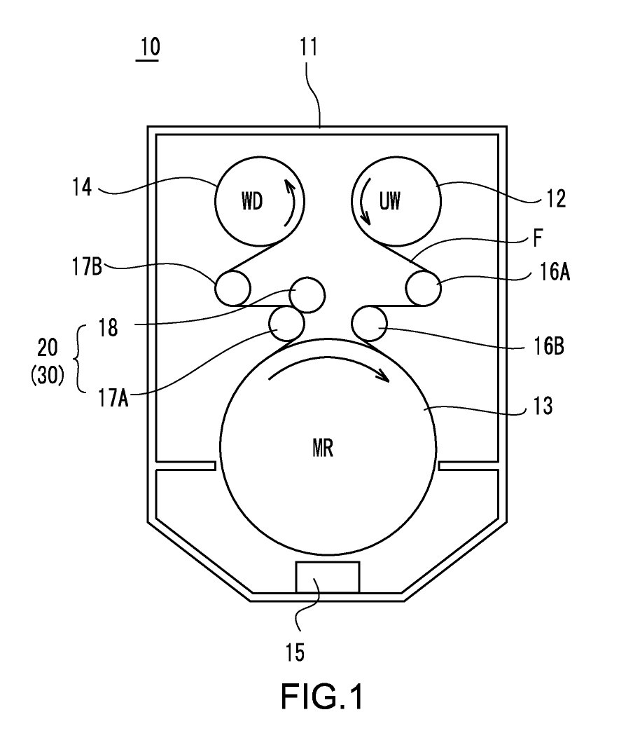

FIG. 1 is a schematic structural diagram of a roll-to-roll vacuum vapor deposition apparatus 10 according to an embodiment of the present invention. The roll-to-roll vacuum vapor deposition apparatus 10 is an apparatus that successively deposits a predetermined evaporation material on one surface of a long base film F.

Though not shown, a vacuum chamber 11 is connected to a vacuum exhaust means and is capable of being exhausted to a predetermined vacuum degree. A payout roller 12, a cooling main roller 13, and a take-up roller 14 are provided inside the vacuum chamber 11, and an evaporation source 15 constituting a deposition mechanism is provided at a position opposed to the main roller 13. The base film F is successively paid out from the payout roller 12 and taken up by the take-up roller 14 after a layer is deposited at a position opposed to the evaporation source 15 while being cooled by the main roller 13.

Moreover, guide rollers 16A and 16B that guide the traveling base film F before the deposition are provided between the payout roller 12 and the main roller 13, and a guide unit 20 and a guide roller 17B that guide the traveling base film F after the deposition are provided between the main roller 13 and the take-up roller 14. The guide rollers 16A and 16B, the main roller 13, the guide unit 20, and the guide roller 17B constitute a “traveling mechanism” according to the present invention.

Here, the base film F is constituted of a long plastic film having an insulation property and cut at a predetermined width. For example, an OPP (oriented polypropylene) film, a PET (polyethylene terephthalate) film, or a PI (polyimide) film is used. The base film F may be a metal foil.

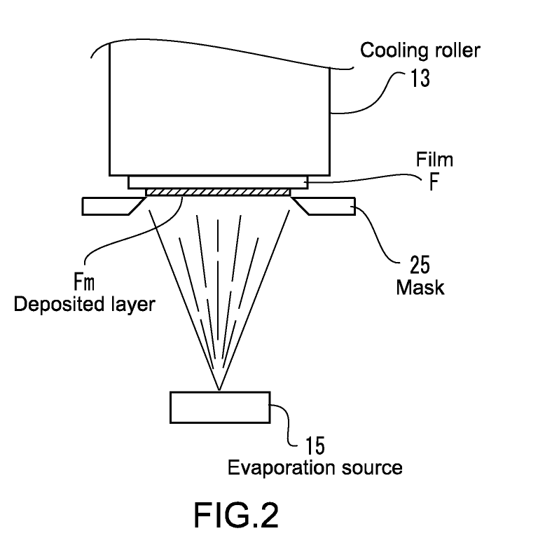

In this embodiment, the base film F corresponds to that in which side edge portions of a deposition surface are assumed as non-deposition areas or those in which side edge portions are assumed as unused areas even when deposition is performed on the entire surface of the deposition surface. For setting the side edge portions of the deposition surface as non-deposition areas, there is a method of disposing a mask 25 between the main roller 13 and the evaporation source 15 as shown in FIG. 2, for example. The side edge portions of the base film F are covered by the mask 25, and a deposited layer Fm is deposited only at a deposition area at a center portion.

The payout roller 12 and the take-up roller 14 each have an independent rotary drive portion and structured to successively pay out and take up the base film F at a constant velocity. The main roller 13 is tubular and made of metal such as stainless steel and iron and includes a rotary drive portion. Inside, the main roller 13 has a cooling mechanism such as a cooling medium circulation system. The base film F is deposited with, on a deposition surface on an outer surface side thereof, an evaporation material from the evaporation source 15 while a non-deposition surface thereof is subjected to cooling processing by being brought into close contact with the main roller 13.

The evaporation source 15 accommodates the evaporation material and has a mechanism for causing the evaporation material to evaporate by heating using a well-known technique such as resistance heating, induction heating, and electron beam heating. The evaporation source 15 is disposed below the main roller 13 and causes vapor of the evaporation material to adhere onto the deposition surface of the base film F on the main roller 13 opposed thereto, to thus form a deposited layer.

Though the evaporation material is not particularly limited, in addition to a metal element such as Al (aluminum), Co (cobalt), Cu (copper), Ni (nickel), and Ti (titanium), two or more metals such as Al—Zn (zinc), Cu—Zn, and Fe (iron)-Co, or a multi-component alloy is applicable. In addition, the number of evaporation source 15 is not limited to one, and a plurality of evaporation sources may be provided.

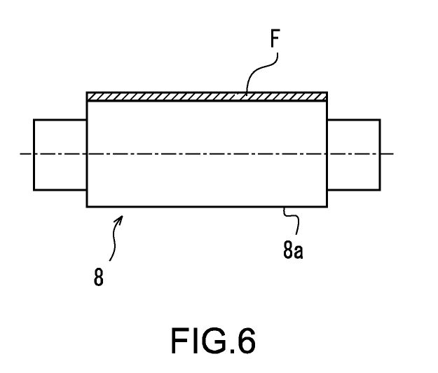

The guide roller 16A and the guide roller 17B are each constituted of a cylindrical roll body that guides the traveling base film F by coming into contact with the non-deposition surface of the base film F and each have the same structure as a guide roller 8 shown in FIG. 6, for example. Moreover, the guide roller 16B is constituted of a cylindrical roll body that guides the traveling base film F by coming into contact with the deposition surface of the base film F and has the same structure as the guide rollers 16A and 17B described above. It should be noted that although the guide rollers 16A, 16B, and 17B are structured as free rollers that rotate to pass on the traveling base film F, those rollers may each have an independent rotation mechanism portion.

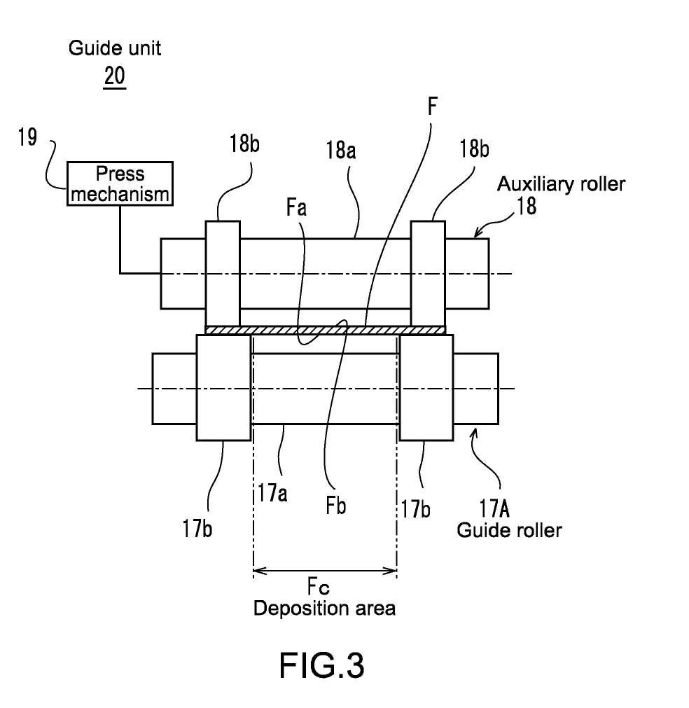

The guide unit 20 is provided between the main roller 13 and the guide roller 17B and has a guide function for conveying the base film F subjected to deposition processing toward the take-up roller 14. FIG. 3 is a side view showing a structural example of the guide unit 20 of this embodiment. The guide unit 20 shown in FIG. 3 includes the guide roller 17A and an auxiliary roller 18.

The guide roller 17A is constituted of a cylindrical roll body that includes a roll surface 17a opposed to a deposition surface Fa of the base film F, and a shaft position thereof is fixed inside the vacuum chamber 11. On the roll surface 17a of the guide roller 17A, a pair of annular guide portions 17b, 17b that support the side edge portions on both sides of a deposition area Fc of the deposition surface Fa of the base film are formed protrusively, and a certain gap is formed between the deposition area Fc and the roll surface 17a. The guide portions 17b, 17b may be integrally formed on the roll surface 17a of the guide roller 17A or may be constituted as a separate component.

It should be noted that although the guide roller 17A is structured as a free roller that rotates to pass on the traveling base film F, it may have an independent rotation mechanism portion. Moreover, a constituent material of the guide portions 17b is not particularly limited, and an elastic body formed of rubber or the like may be used in addition to metal and a resin.

On the other hand, the auxiliary roller 18 is constituted of a cylindrical roll body opposed to the guide roller 17A. On a roll surface 18a of the auxiliary roller 18, a pair of annular press portions 18b, 18b that press the side edge portions of the base film F against the guide portions 17b, 17b of the guide roller 17A by being brought into contact with a non-deposition surface Fb side of the base film F are formed protrusively. The press portions 18b, 18b may be integrally formed on the roll surface 18a of the auxiliary roller 18 or may be constituted as a separate component.

A press mechanism 19 for pressing the auxiliary roller 18 toward the guide roller 17A is connected to a shaft portion of the auxiliary roller 18. The press mechanism 19 includes a bias means such as a spring and a cylinder and cooperates with the guide roller 17A whose shaft position is fixed to generate a predetermined nip force with respect to the side edge portions of the base film F. As a result, bending of the base film F as well as a deviation of a traveling position of the base film F is prevented.

It should be noted that although the auxiliary roller 18 is structured as a free roller that rotates to pass on the traveling base film F, it may have an independent rotation mechanism portion. Moreover, a constituent material of the press portions 18b is not particularly limited, and an elastic body formed of rubber or the like may be used in addition to metal and a synthetic resin.

In this embodiment having the structure as described above, in the vacuum chamber 11 exhausted to a predetermined reduced-pressure atmosphere, the base film F is successively paid out from the payout roller 12 and taken up by the take-up roller 14 after the traveling base film F is subjected to deposition processing on the main roller 13.

At this time, according to this embodiment, although the base film F on which a deposited layer is formed is conveyed while the deposition area Fc thereof is opposed to the roll surface 17a of the guide roller 17A, since the base film F is conveyed while side edge portions thereof are nipped by the guide portions 17b, 17b of the guide roller 17A and the press portions 18b, 18b of the auxiliary roller 18, the deposition area Fc does not come into contact with the roll surface 17a of the guide roller 17A. As a result, it is possible to protect the deposition area Fc and prevent damages and deterioration of performance of a deposited layer due to a contact with the roll surface 17a.

Moreover, since this embodiment is structured to convey the base film F in a state where side edge portions of the film are nipped by the guide unit 20, it is possible to realize stable traveling performance of the base film F and secure favorable take-up performance of the base film F in the take-up roller 14.

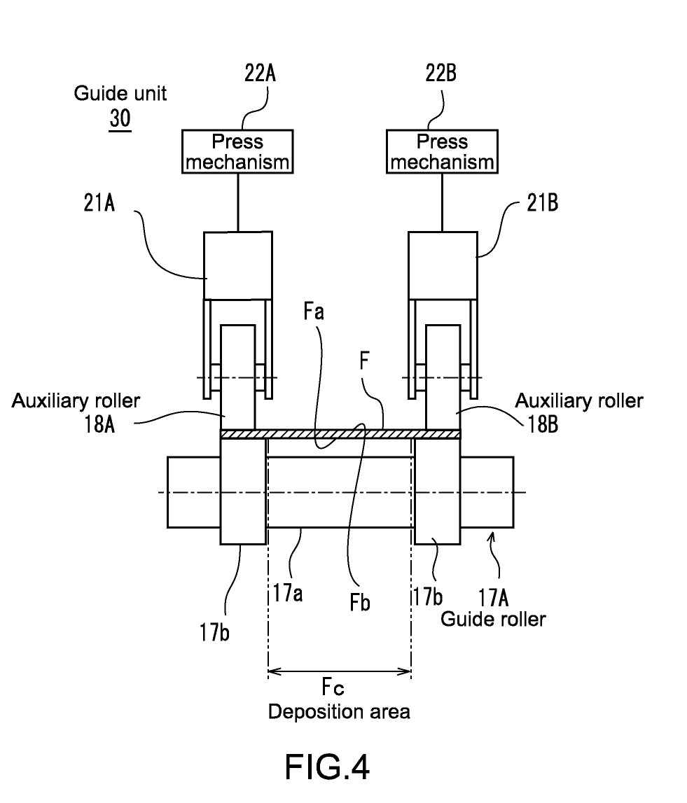

FIG. 4 is a front view showing a structural example of a guide unit 30 according to another embodiment of the present invention. The guide unit 30 shown in FIG. 4 includes the guide roller 17A having the structure described above and a pair of auxiliary rollers 18A and 18B that come into contact with the non-deposition surface Fb side of the base film F and presses the side edge portions of the base film F toward the pair of guide portions 17b, 17b of the guide roller 17A.

Rotary shafts of the auxiliary rollers 18A and 18B are rotatably supported by support brackets 21A and 21B, respectively, and the support brackets 21A and 21B are coupled to mutually-independent press mechanisms 22A and 22B, respectively. The press mechanisms 22A and 22B each include a bias means such as a spring and a cylinder and cooperate with the guide roller 17A whose shaft position is fixed to generate a predetermined nip force with respect to the side edge portions of the base film F. As a result, bending of the base film F as well as a deviation of a traveling position of the base film F is prevented.

It should be noted that although the auxiliary rollers 18A and 18B are structured as free rollers that rotate to pass on the traveling base film F, they may have an independent rotation mechanism portion. Moreover, a constituent material of the auxiliary rollers 18A and 18B is not particularly limited, and an elastic body formed of rubber or the like may be used in addition to metal and a resin.

Since the base film F is conveyed while side edge portions thereof are nipped by the guide portions 17b, 17b of the guide roller 17A and the auxiliary rollers 18A and 18B in this embodiment having the structure as described above, the deposition area Fc of the base film F does not come into contact with the roll surface 17a of the guide roller 17A. As a result, it is possible to protect the deposition area Fc and prevent damages and deterioration of performance of a deposited layer due to a contact with the roll surface 17a.

Moreover, since this embodiment is structured to convey the base film F in a state where side edge portions of the film are nipped by the guide unit 30, it is possible to realize stable traveling performance of the base film F and secure favorable take-up performance of the base film F in the take-up roller 14.

Furthermore, since this embodiment is structured to press the side edge portions of the base film F against the guide portions 17b, 17b of the guide roller 17A with the auxiliary rollers 18A and 18B, respectively, traveling performance of the base film F can be controlled as well as optimally adjust a pressing force with respect to each of the edge portions of the base film F.

The embodiments of the present invention have been described heretofore. However, the present invention is of course not limited thereto and can be variously modified based on the technical idea of the present invention.

For example, in the above embodiments, the guide unit 20 (30) according to the present invention has been structured by disposing the auxiliary roller 18 (18A, 18B) opposite to the guide roller 17A that is opposed to the deposition surface of the base film F after the deposition. However, it is also possible to dispose the auxiliary roller opposite to the guide roller 16B (FIG. 1) that is opposed to the deposition surface of the base film F before the deposition and thus structure a guide unit.

Alternatively, an auxiliary roller having the structure described above may be disposed opposite to every guide roller. As a result, the base film can be taken up while surfaces on both sides of the base film are protected.

Moreover, in the above embodiments, descriptions have been given on the example in which a metal layer is deposited by applying the vacuum vapor deposition method that uses the evaporation source 15 as a deposition means. However, the present invention is not limited thereto, and other deposition methods for depositing a metal layer or a nonmetal layer, such as a sputtering method and various CVD methods are also applicable, and a deposition means such as a sputtering target can be employed as appropriate based on those deposition methods. Moreover, the main roller 13 is not limited to a case where it is structured as a cooling roller and may instead be structured as a heating roller.

Furthermore, the above embodiments have described an example in which the film conveyor apparatus of the present invention is applied to a deposition apparatus such as a roll-to-roll vacuum vapor deposition apparatus. However, the present invention is not limited thereto and is also applicable to a film processing apparatus in which a heating processing means, a plasma processing means, or the like is disposed between a payout roller and a take-up roller and heating processing, plasma processing, or the like is carried out while causing a base film to travel. In addition, the present invention is also applicable to an apparatus that merely conveys a base film from a payout roller to a take-up roller. In this case, the chamber is not limited to a reduced-pressure atmosphere and may be controlled to an atmospheric pressure.

What is claimed is:

1. A film conveyor apparatus conveying a base film in a vacuum chamber, comprising:
a payout roller;
a take-up roller; and
a traveling mechanism that is provided between the payout roller and the take-up roller and includes a guide unit including a guide roller and an auxiliary roller, the guide roller including a pair of annular guide portions that support side edge portions of the base film, the auxiliary roller being opposed to the guide roller and pressing the side edge portions of the base film against the pair of guide portions.

2. The film conveyor apparatus according to claim 1, further comprising any one of
a deposition mechanism to deposit a layer on the base film, a heating mechanism to heat the base film, and a plasma processing mechanism to subject the base film to plasma processing, between the payout roller and the take-up roller.

3. The film conveyor apparatus according to claim 1,
wherein the auxiliary roller includes a pair of annular press portions that press the side edge portions of the base film against the pair of guide portions at the same time.

4. The film conveyor apparatus according to claim 1,
wherein the auxiliary roller is provided in a pair so that the side edge portions of the base film can be pressed independently against the pair of guide portions.

5. The film conveyor apparatus according to claim 1,
wherein the traveling mechanism includes a main roller that cools or heats the base film by being brought into close contact with a non-deposition surface of the base film, and
wherein the guide roller is provided between the main roller and the take-up roller.

6. A roll-to-roll vacuum deposition method, comprising:
successively paying out a base film in a reduced-pressure atmosphere;
depositing a layer on at least one surface of the base film; and
nipping the base film on which a layer is deposited at side edge portions thereof and conveying the base film to a take-up portion.
